(19) United States
(12) Patent Application Publication
(10) Pub. No.: US 2009/0289363 A1
(43) Pub. Date: Nov. 26, 2009

(54) Fine-Pitch Ball Grid Array Package Design

(75) Inventors: Keven Dale Coates, Cypress, TX (US); Thomas William Krauskopf, Katy, TX (US)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 12/126,104

(22) Filed: May 23, 2008

(51) Int. Cl. H01L 23/48; H01L 21/00

(52) U.S. Cl. 257/738; 438/6; 257/E21.526; 257/E23.021

(57) ABSTRACT

In one aspect, a method for configuring a ball grid array is disclosed. The method may include identifying a number of balls for use in a ball grid array, determining a number of rows and a number of columns for the ball grid array, and populating the ball grid array at least in part with a plurality of ball-space groupings. The method may also include allocating an unpopulated portion of an area bounded by the at least one first outside row, the at least one second outside row, the at least one first outside column, and the at least one second outside column, to be free of balls. The method may also include routing a signal line from a ball of at least one ball-space grouping to a space of the at least one ball-space grouping and routing the signal line to a substrate layer through a via.

### FIELD OF THE INVENTION

This invention relates generally to design of integrated circuits. More particularly, the invention relates to the placement of balls of solder in a ball grid array (herein, “BGA”) to conduct electrical signals between a printed circuit board (herein, “PCB”) and an integrated circuit placed on the PCB.

### BACKGROUND OF THE INVENTION

The BGA and other high density array packages are used by PCB manufacturers to reduce board space required for a particular product. To reduce board space, PCB manufacturers have used ever-smaller pitch ball spacing, i.e., spacing between ball row and ball columns. To use these ever-smaller pitches, PCB manufacturers have been required to use expensive techniques to drill small vias, that is, tunnels through which electrical lines are routed, for use with the small pitches to route out signals from the BGA. Expensive techniques to drill small vias may be needed because mechanical drills are typically limited to vias diameters of 0.008 inches or greater.

Ball grid array package designs that do not require expensive via drilling techniques and that do not incur the associated increased board costs, including the placement of balls in BGAs, are desirable.

### SUMMARY OF THE INVENTION

In one aspect, a method for configuring a ball grid array includes but is not limited to identifying a number of balls for use in a ball grid array; determining a number of rows and a number of columns for the ball grid array; and populating the ball grid array at least in part with a plurality of ball-space groupings.

In one aspect, a system for configuring a ball grid array includes but is not limited to circuitry configurable for accepting input for identifying a number of balls for use in a ball grid array; circuitry configurable for determining a number of rows and a number of columns for the ball grid array; and circuitry configurable for populating the ball grid array at least in part with a plurality of ball-space groupings

In one aspect, an article includes a medium storing instructions that, if executed, enable a processor-based system to accept input to identify a number of balls required in a ball grid array; determine a number of rows and a number of columns for the ball grid array; and populate the ball grid array at least in part with a plurality of ball-space groupings.

In one aspect, a computer system includes but is not limited to a memory and a processor operably coupleable to the memory to accept input to identify a number of balls required in a ball grid array, determine a number of rows and a number of columns for the ball grid array, and populate the ball grid array at least in part with a plurality of ball-space groupings.

In one aspect, an electronic device includes but is not limited to an integrated circuit device including a ball grid array, the ball grid array including at least one first outside row on a first side and at least one second outside row on a second side populated with balls; at least one first outside column on a third side and at least one second outside column on a fourth side populated with balls; and a populated portion of an interior area, wherein the populated portion of the area is populated with a plurality of ball-space groupings, and wherein the interior area includes an area bounded by the at least one first outside row, the at least one second outside row, the at least one first outside column, and the at least one second outside column.

In one or more various aspects, related articles, systems, and devices include but are not limited to circuitry, programming, electro-mechanical devices, or optical devices for effecting the herein-referenced method aspects; the circuitry, programming, electro-mechanical devices, or optical devices can be virtually any combination of hardware, software, and firmware configured to effect the herein-referenced method aspects depending upon the design choices of the system designer skilled in the art.

In addition to the foregoing, various other method, device, and system aspects are set forth and described in the teachings such as the text (e.g., claims or detailed description) or drawings of the present disclosure.

The foregoing is a summary and thus contains, by necessity, simplifications, generalizations and omissions of detail; consequently, those skilled in the art will appreciate that the summary is illustrative only and is not intended to be in any way limiting. Other aspects, features, and advantages of the devices, processes, or other subject matter described herein will become apparent in the teachings set forth herein.

### BRIEF DESCRIPTION OF THE DRAWINGS

FIG. 1 shows a typical computer system with a graphics controller including an exemplary BGA layout using the invention;

FIG. 2 shows a high-level flow chart of an embodiment of a method of making a BGA, including populating the outside rows and columns of the BGA;

FIG. 3 shows a high-level flow chart of another embodiment of a method of making a BGA, including populating the interior of the BGA;

FIG. 4 shows a high-level flow chart of other embodiments of a method of making a BGA, including routing a signal line from a ball and including allocating a portion of BGA to be free of balls;

FIG. 5 shows a high-level flow chart of another embodiment of a method of making a BGA, including routing signal lines from balls to a shared via;

FIG. 6 shows some exemplary BGA embodiments;

FIG. 7 shows a portion of the outside rows and columns of the exemplary BGA layout embodiments of FIG. 6;

FIG. 8 shows a portion of the interior of the exemplary BGA layout embodiments of FIG. 6, partially populated with balls and spaces;

FIG. 9 shows a portion of the interior of the exemplary BGA layout embodiments of FIG. 6, partially unpopulated by balls; and

FIG. 10 shows a cross-section of a portion of the exemplary BGA layout embodiments of FIG. 6.

While the invention is subject to various modifications and alternative forms, specific embodiments thereof are shown by way of example in the drawings and the accompanying detailed description. It should be understood, however, that the drawings and detailed description are not intended to limit the invention to the particular embodiment. This disclosure is instead intended to cover all modifications, equivalents, and alternatives falling within the scope of the present invention as defined by the appended claims.

### NOTATION AND NOMENCLATURE

Certain terms are used throughout the following description and claims to refer to particular system components and configurations. As one skilled in the art will appreciate, companies may refer to a component by different names. This document does not intend to distinguish between components that differ in name but not function. In the following discussion and in the claims, the terms “including” and “comprising” are used in an open-ended fashion, and thus should be interpreted to mean “including, but not limited to . . . ”. Also, the terms “couple” or “couples” or “coupleable” is intended to mean either an indirect or direct electrical or wireless connection. Thus, if a first device couples to a second device, that connection may be through a direct electrical or wireless connection, or through an indirect electrical or wireless connection by means of other devices and connections.

### DETAILED DESCRIPTION

In the following detailed description, reference is made to the accompanying drawings, which form a part hereof. The illustrative embodiments described in the detailed description, drawings, and claims are not meant to be limiting. Other embodiments may be utilized, and other changes may be made, without departing from the spirit or scope of the subject matter presented here.

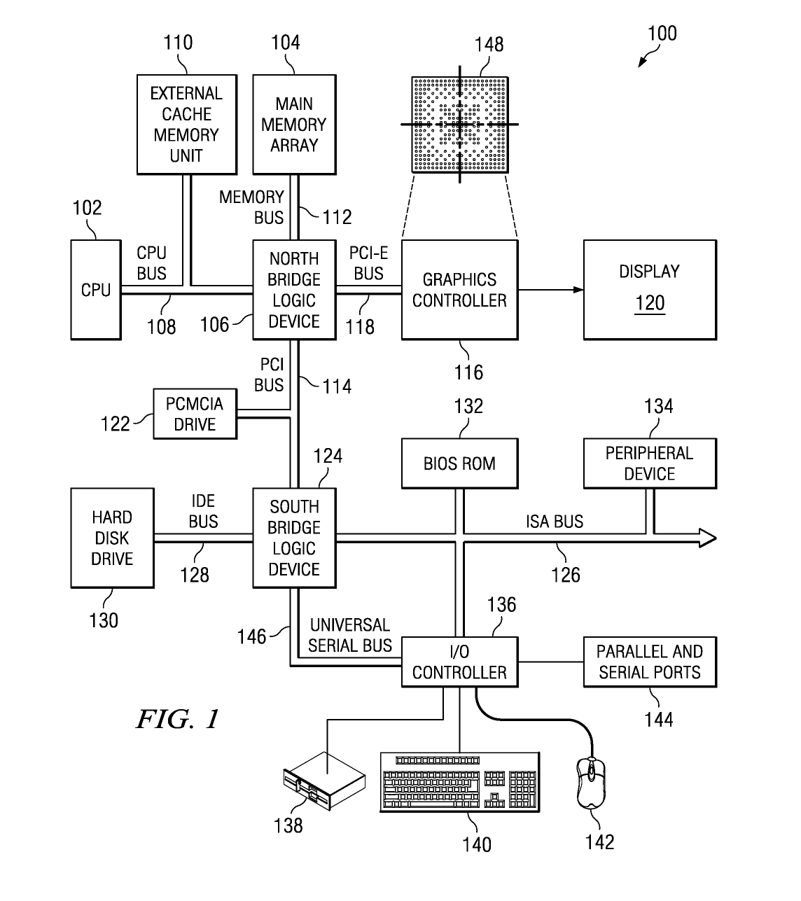

Turning now to FIG. 1, a computer system 100 that includes a BGA 148 is shown. In this exemplary computer system 100, the BGA 148 is shown as being a part of an integrated circuit serving as the graphic controller 116. The exemplary BGA 148 is not limited to being included in the graphics controller 116; it is shown as included in a specific component for illustrative purposes only. One skilled in the art will recognize that a BGA 148 may be used in a number of devices not limited to graphics controllers.

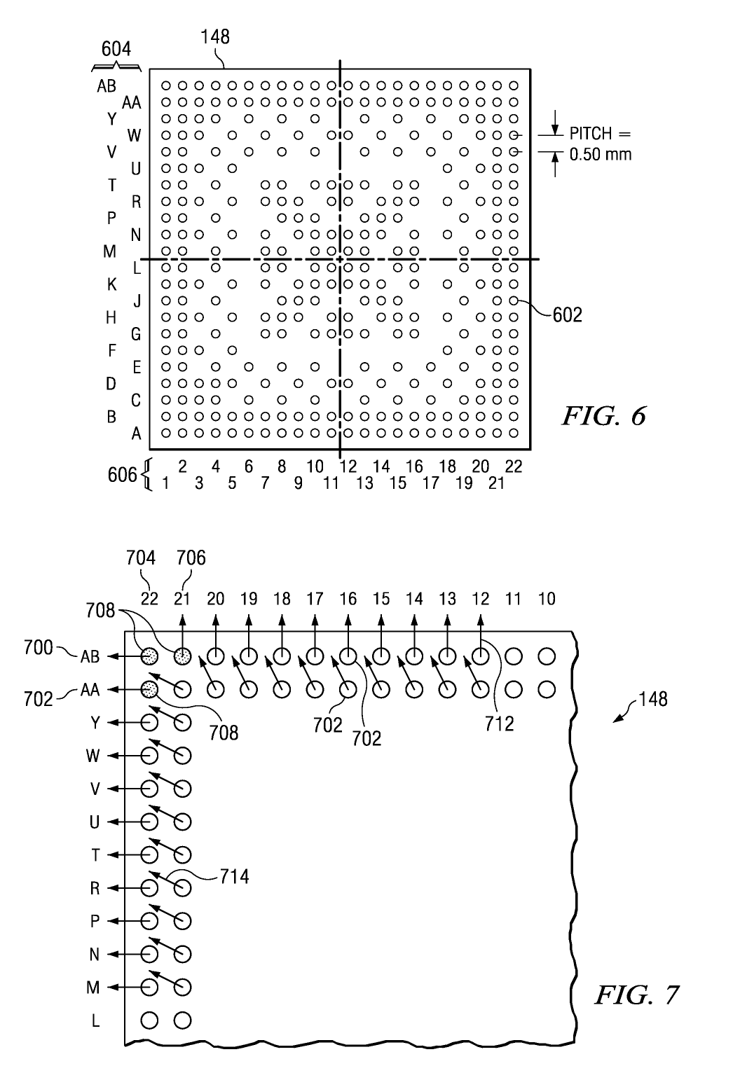

The BGA 148 is an array of solder balls in a grid pattern, as shown herein in FIGS. 6, 7, 8, 9, and 10. The solder balls of the BGA 148 are used to provide electrically conductive paths from an integrated circuit to the PCB on which the integrated circuit is placed. The integrated circuit is placed on the PCB that has pads in a grid pattern so that the solder balls of the BGA may be aligned with the pads of the PCB. The assembly is heated, melting the solder balls. The solder balls then cool and solidify, providing electrically conductive paths connecting the integrated circuit and the PCB. Signals are sent to and received from the graphics controller 116 by means of the electrically conductive paths provided by the BGA 148. Here, the PCB on which the graphics controller 116 is placed provides signal paths to and from the other components of the exemplary computer system 100. The BGA 148 depicted in FIG. 1 and used in examples herein is a square array, but embodiments of the invention may pertain to or include rectangular BGAs. In addition, embodiments of the invention may pertain to or include regular or irregular arrays of three or more sides, such as triangular, quadrilateral, pentagonal, hexagonal, and octagonal arrays. BGAs designed according to or incorporating embodiments of the invention may reduce the PCB area required for a product by permitting more efficient use of the area.

The exemplary computer system 100 may be configured in any number of ways, including as a personal digital assistant (PDA), SmartPhone, laptop unit, a desktop unit, a network server, cell phone or any other configuration. The computer system 100 may include a central processing unit (CPU) 102 coupled to a main memory array 104 and to a variety of other peripheral computer system components through an integrated bridge logic device (“North bridge logic device”) 106. The CPU 102 may comprise, for example, a processor belonging to the Intel® Pentium® Dual Core or Core™ 2 families of processors, or a processor featuring the PowerPC® architecture. The CPU 102 may couple to the North bridge logic device 106 by way of a CPU bus 108, or the North bridge logic device 106 may be integrated into the CPU 102. An external cache memory unit 110 further may couple to the CPU bus 108 or directly to the CPU 102. The main memory array 104 may couple to the North bridge logic device 106 through a memory bus 112. The North bridge logic device 106 may couple the CPU 102 and main memory array 104 to the peripheral devices in the system through a Peripheral Component Interconnect (PCI) bus 114 or other expansion bus. The computer system 100 may include a graphics controller 116 that may couple to the North bridge logic device 106 through an expansion bus, e.g., the PCI Express® (“PCI-E”) bus 118 or through the PCI bus 114. As discussed herein, the graphics controller 116 includes the exemplary BGA 148. The graphics controller 116 may embody a typical graphics accelerator generally known in the art to render three-dimensional data structures on display 120. The display 120 comprises any suitable electronic display device upon which an image or text can be represented.

The computer system 100 optionally may include a Personal Computer Memory Card International Association (PCMCIA) drive 122 coupled to the PCI bus 114. Another bridge logic device (“South bridge logic device”) 124 typically may couple the PCI bus 114 to that expansion bus. In FIG. 1, the South bridge logic device 124 couples the PCI bus 114 to an Industry Standard Architecture (ISA) bus 126 and to an Integrated Drive Electronics (IDE) bus 128. In FIG. 1, the IDE bus 128 shown in FIG. 1 couples to Hard Disk Drive (HDD) 130. Various ISA-compatible devices are shown coupled to the ISA bus 126, including a BIOS ROM 132. A peripheral device 134 such as a disk drive may also be coupled to the ISA bus 126. The South bridge logic device 124 supports an input/output (I/O) controller 136 that operatively couples to basic input/output devices such as a floppy disk drive 138, a keyboard 140, a mouse 142, general purpose parallel and serial ports 144, and various input switches such as a power switch and a sleep switch (not shown). The I/O controller 136 may couple to the South bridge logic device 124 by way of an ISA bus 126 in FIG. 1. A universal serial bus 146 may provide an additional connection between the I/O controller 134 and South bridge logic device 124.

Embodiments of the invention are not limited to the BGA 148 described herein. An integrated circuit device or a computer system component that incorporates an embodiment of the invention may be used in a variety of computing systems, not limited to the computer system 100 depicted in FIG. 1, including cell phones, personal digital assistants, and cameras.

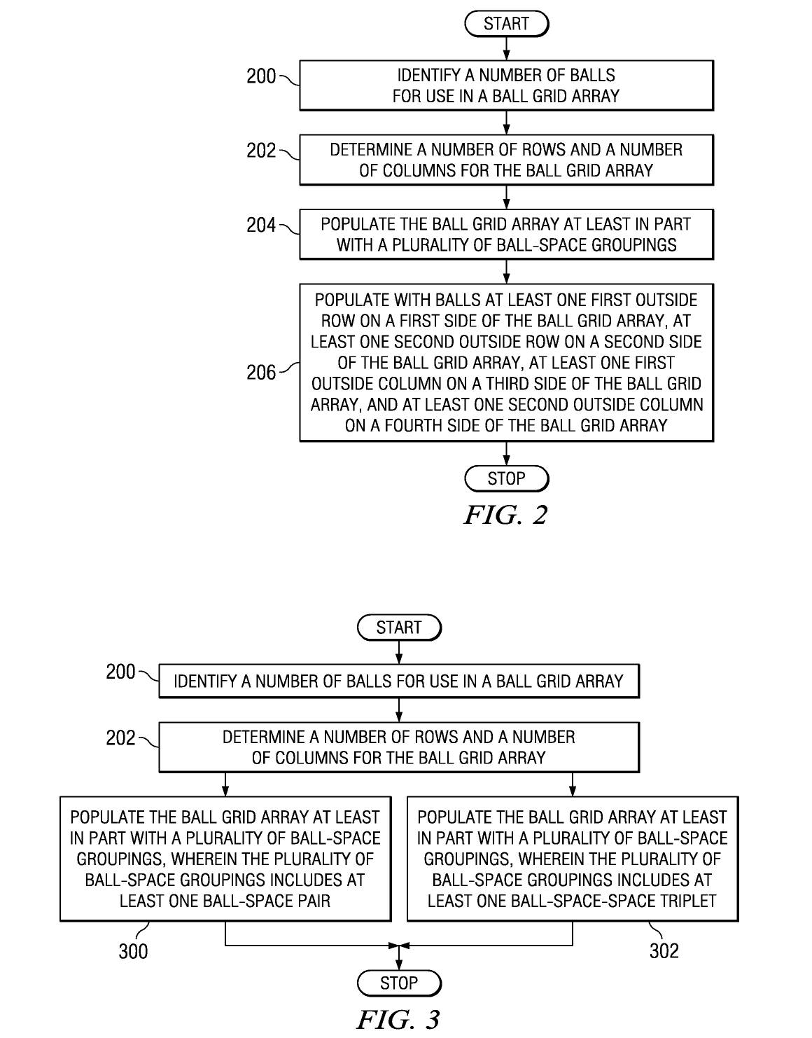

Turning now to FIG. 2, a high-level flow chart of a method embodiment is illustrated. The embodiment shown may include one or more of the following operations: 200, 202, 204, and 206.

Operation 200 depicts an operation to identify a number of balls for use in a BGA. Operation 200 may be performed, for example, with respect to a particular BGA such as the BGA 148 to be used as the graphics controller 116 of FIG. 1. In this example, operation 200 may be used to identify a number of balls for use based on the number and type of connections to be made with the BGA 148. In a particular exemplary application, the number of balls for use in the BGA may be identified to be 484 balls as a first approximation. This first approximation may be refined by considering the number of balls that are electrically common and therefore may share a via. A via is an electrical path that connects a ball with a pin of the integrated circuit device of which the BGA is a component. Some subset of the 484 balls may be identified as electrically common with other balls, allowing the number of balls for use in the BGA 148 to be identified as 329. The number of balls used in the example for FIG. 2, 329 balls, includes an extra ball included to allow the device to be oriented correctly in an assembly machine. Such an orientation ball is shown in row D, column 4 of the array illustrated in FIG. 6. Where balls are electrically common with each other, they may share vias, permitting more efficient use of the area of the PCB incorporating the BGA. Skilled artisans will recognize that various design considerations may be used to arrive at the number of balls for use in the BGA based on the specific application of the PCB. Further, a number of methods of calculation and a number of calculation tools, including but not limited to design expertise, a calculator, or a suitably programmed computer, may be used to perform operation 200.

Operation 202 shows an operation to determine a number of rows and a number of columns for the BGA. Continuing the example used to illustrate operation 200, the number of rows and the number of columns for the BGA may be determined such that the number of balls identified in operation 200 may be accommodated. Typically, the BGA will have a number of rows equal to a number of columns, but the BGA is not limited to an equal number of rows and columns. In the exemplary BGA 148 of FIG. 1, the number of rows and the number of columns are equal. The exemplary BGA 148 has 22 rows and 22 columns to accommodate 329 balls as identified in operation 200.

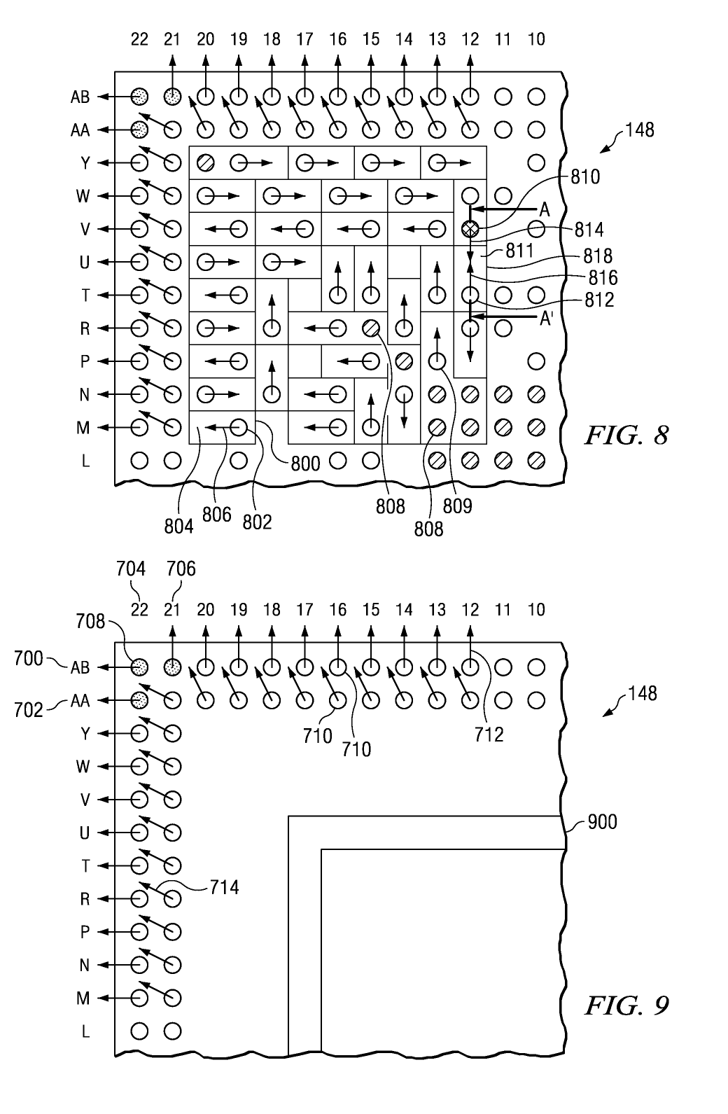

Operation 204 illustrates an operation to populate the BGA at least in part with a plurality of ball-space groupings. Continuing the examples used to illustrate operations 200 and 202, the BGA 148 is populated at least in part with one or more ball-space groupings. A ball-space grouping is any grouping of ball and spaces considered together as a unit for the purpose of making a BGA. Among the ball-space groupings used in the examples herein are ball-space pairs. A ball-space pair includes a block of two spaces, oriented in any direction, with one space populated with a ball, adjacent to one space of equal size to the populated space but not populated by a ball, such as ball-space pair 800 in FIG. 8 (described below). A ball-space grouping may also be, for example, a ball-space-space triplet, which includes a ball and two spaces unoccupied by balls. A ball-space grouping is not limited to the exemplary ball-space pair and the exemplary ball-space-space triplet described herein. The spaces of these ball-space groupings ensure that there is enough room for a hole via to route the signal from the ball of the ball-space grouping out of the array in the smaller BGAs made possible by the invention. Other considerations, including but not limited to thermal stability and drop test stresses, may be taken into account when placing balls and ball-space groupings. Those skilled in the art will recognize that the type of ball-space groupings selected to populate the BGA will depend on considerations including but not limited to the constraints on routing signals between the balls of the outside rows or columns. For instance, a BGA may have a pitch so small that signals cannot be routed between the balls of the outside rows or outside columns. Ball-space-space triplets may be required to provide spaces for routing signals through substrate layers in the interior of the ball gate array using vias.

Operation 206 illustrates an operation to populate with balls at least one first outside row on a first side of the BGA, at least one second outside row on a second side of a second side of the BGA, at least one first outside column on a third side of the BGA, and at least one second outside column on a fourth side of the BGA. Continuing the examples used to illustrate operations 200, 202, and 204, operation 206 may include populating the BGA 148 as depicted in FIG. 6 as follows: rows A and B (at least one first outside row on a first side of the BGA); rows AA and AB (at least one second outside row on a second side if the BGA); columns 1 and 2 (at least one first outside column on a third side of the BGA); and columns 21 and 22. Typically, a BGA will be designed with two populated outside rows and two populated outside columns; this situation is illustrated by BGA 148 in FIG. 1. An embodiment is not, however, limited to populating with balls two outside rows and columns. Those skilled in the art will recognize that the number of populated outside rows need not equal the number of populated outside columns, and that a different number of outside rows or columns may be populated on either side of a BGA (for example, a BGA may have one populated outside row on either side and two populated outside columns, or one populated outside row (or column) on one side and two populated outside rows (or columns) on the other side). A BGA may include the optional feature of three non-critical signal pins 708 at the corners as depicted in FIG. 7 (described below). Operation 204 and operation 206 may take place in either order or at the same time.

Turning now to FIG. 3, a high-level flow chart of another embodiment of a method of making a BGA, including populating the interior of the BGA is shown. The depicted embodiment may include one or more of the following operations: 200 (described above), 202 (described above), 300, and 302.

Operation 300 depicts an operation to populate the BGA at least in part with a plurality of ball-space groupings, wherein the plurality of ball-space groupings includes at least one ball-space pair. A ball-space grouping is any grouping of ball and spaces considered together as a unit for the purpose of making a BGA. Among the ball-space groupings used in the examples herein are ball-space pairs. A ball-space pair includes a block of two spaces, oriented in any direction, with one space populated with a ball, adjacent to one space of equal size to the populated space but not populated by a ball, such as ball-space pair 800 in FIG. 8 (described below). Continuing the examples used to illustrate operations 200 and 202, populating the BGA 148 at least in part with more than one ball-space grouping may include populating the BGA 148 with at least one ball-space pair.

In an exemplary case in which the outer two rows and columns of the BGA are to be populated with balls and the BGA is to be populated with ball-space groupings comprising only ball-space pairs, the following equation may be used to approximate the number of balls in the BGA:

B=4R+4(C−4)+0.5(R−4)(C−4) Eqn. 1

where B=the number of balls in the BGA,

R=the number of rows in the BGA,

C=the number of columns in the BGA.

For the first term and the second term of Equation 1, the factor of 4 represents the number of outside rows and columns to be filled completely. In the third term, the factor of 0.5 represents the fill-rate of 50% associated with ball-space pairs because there is one ball for every space in the interior area of the BGA.

Operation 302 shows an operation to populate the BGA at least in part with a plurality of ball-space groupings, wherein the plurality of ball-space groupings includes at least one ball-space-space triplet. Continuing the examples used to illustrate operations 200 and 202, populating the BGA 148 at least in part with more than one ball-space grouping may include populating the BGA 148 with at least one ball-space-space triplet. A ball-space-space triplet includes a block of three spaces, arranged in a line, oriented in any direction, with one space at one end of the block populated with a ball, and adjacent to one space of equal size to the populated space but not populated by a ball, that unpopulated space adjacent to a second similarly sized and unpopulated space.

In an exemplary case in which the outer single rows and columns of the BGA are to be populated with balls and the BGA is to be populated with ball-space groupings comprising only ball-space-space triplets, the following formula may be used to approximate the number of balls in the BGA:

B=2R+(C−2)+(R−2)(C−2)/3 Eqn. 2

where B=the number of balls in the BGA,

R=the number of rows in the BGA,

C=the number of columns in the BGA.

In the first term and second term of Equation 2, the factor of 2 represents the number of outside rows and columns on each side of the BGA to be filled completely. In the third term, the factor of ⅓ represents the fill-rate associated with ball-space-space triplets, because there is a ball for every two spaces. Ball-space pairs and ball-space-space triplets may be used in a single BGA.

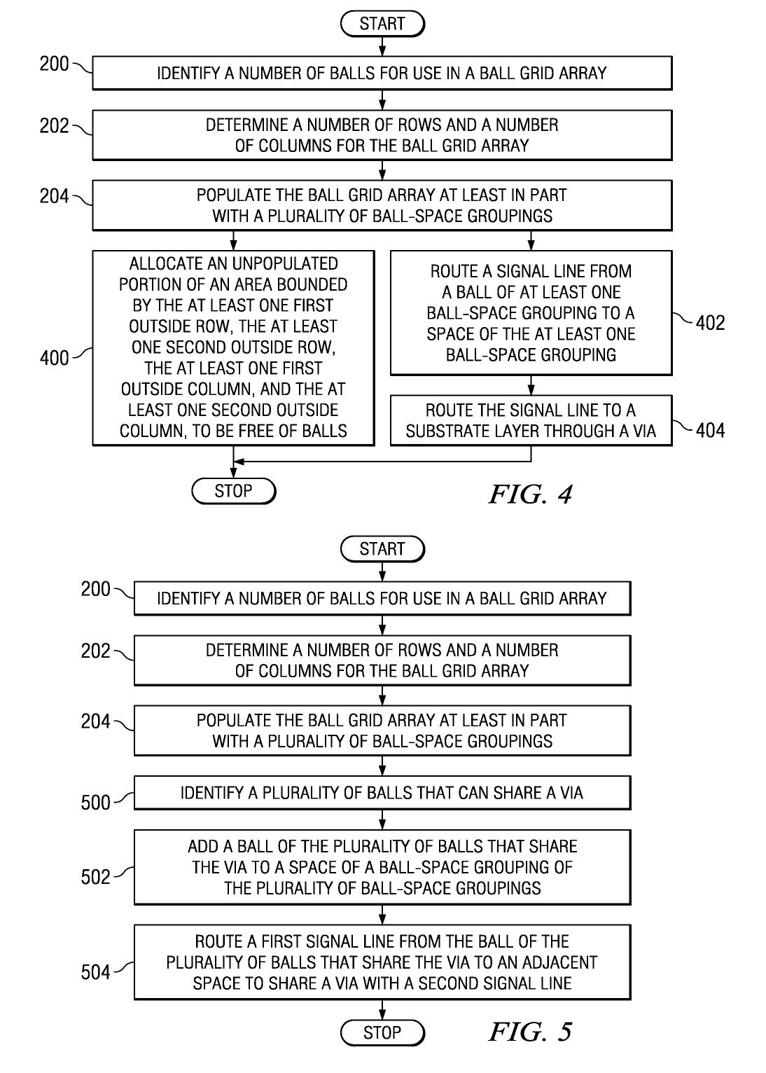

Turning now to FIG. 4, a high-level flow chart of other embodiments of a method of making a BGA, including routing a signal line from a ball and including allocating a portion of the BGA to be free of balls, is shown. The embodiment illustrated may include one or more of the following operations: 200 (described above), 202 (described above), 204 (described above), 400, 402, and 404.

Operation 400 depicts an operation to allocate an unpopulated portion of an area bounded by the at least one first outside row, the at least one second outside row, the at least one first outside column, and the at least one second outside column, to be free of balls. Continuing the examples used to illustrate operations 200, 202, and 204, allocating an unpopulated portion of the BGA 148 may include allocating an area 900 such as a die edge area that is to remain unpopulated for thermal management, as shown in FIG. 9 (described below).

Operation 402 shows an operation to route a signal line from a ball of at least one ball-space grouping to a space of the at least one ball-space grouping. Continuing the examples used to illustrate operations 200, 202, and 204, routing a signal line from a ball of a ball-space grouping to a space of a ball-space grouping may include, for example, in the ball-space pair 800 of FIG. 8 (described below), routing the signal line 806 from the ball 802 to the space 804.

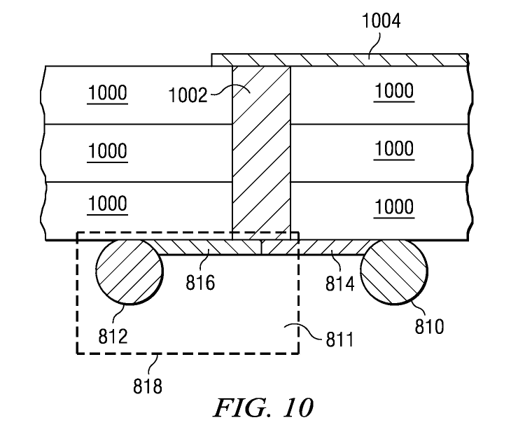

Operation 404 illustrates routing the signal line to a substrate layer through a via. Continuing the examples used to illustrate operations 200, 202, 204, and 402, operation 404 may include routing a signal line from a ball of the BGA to a substrate layer below the BGA through a via. One example of this is illustrated in FIG. 10 (described below), in which a signal line from the ball 812 comprises the signal line 816, a signal line segment in the hole via 1002, and a signal line 1004.

Turning now to FIG. 5, a high-level flow chart of another embodiment of a method of making a BGA, including routing signal lines from balls to a shared via, is depicted. The embodiment shown may include one or more of the following operations: 200 (identifying a number of balls for use in a ball grid array, described above), 202 (determining a number of rows and a number of columns for the ball grid array, described above), 204 (populating the ball grid array at least in part with a plurality of ball-space groupings, described above), 500, 502, and 504.

Operation 500 shows an operation to identify a plurality of balls that can share a via. Continuing the examples used to illustrate operations 200, 202, and 204, identifying a plurality of balls that can share a via may include, for example, identifying balls 810 and 812 of FIGS. 8 and 10 (described below) as ground balls, or alternatively as power balls, that are both adjacent to a space of a ball-space pair that can accommodate a via such as hole via 1002.

Operation 502 illustrates an operation to add a ball of the plurality of balls to a space of a ball-space grouping of the plurality of ball-space groupings. Continuing the examples used to illustrate the operations 200, 202, and 204, and 500, adding a ball of the plurality of balls that can share a via to a space of a ball-space grouping may include, for instance, adding ball 810 to the space of a ball-space pair as illustrated in FIGS. 8 and 10, described below. Having populated an interior portion of the BGA 148 with ball-space pairs, such sharing permits filling the BGA 148 more densely with balls that may share vias by populating some of the spaces of the ball-space pairs with additional balls, permitting more efficient use of the area of the PCB of which the BGA 148 is a part.

Operation 504 depicts an operation to route a first signal line from the ball of the plurality of balls that can share a via to an adjacent space to share a via with a second signal line. Continuing the examples used to illustrate operations of 200, 202, 204, 500, and 502, operation 504 may include, for example, as shown in FIG. 8, routing a signal line from a ball of the BGA to a space that includes a hole via to share the hole via with a signal line from another ball. One example of this is shown in FIGS. 8 and 10 (described below), in which a signal line 814 from a ball 810 to a space 811, which includes a hole via 1002, to share the hole via 1002 with a signal line 816 from a ball 812. Because balls 810 and 812 are both ground balls (or are both power balls), they may share the hole via 1002, with signal lines 814 and 816 routing the balls 810 and 812, respectively, to the hole via 1002.

Turning now to FIG. 6 some embodiments of the exemplary BGA 148, are shown. The exemplary BGA 148 includes a number of balls 602 arranged in rows and columns. In FIG. 6, the rows are labeled with the letters A, B, C, D, E, F, G, H, J, K, L, M, N, P, R, T, U, V, W, and Y, and the letter groups AA and AB, and the columns are numbered 1-22. The row AB is an exemplary row 604 and the column 21 is an exemplary column 606. The pitch, that is, the spacing between the balls or spaces, of the BGA 148 is 0.50 mm, a typical but not limiting pitch for embodiments of the invention.

Turning now to FIG. 7, a portion of the outside rows and columns of the exemplary BGA layout embodiments of FIG. 6, is shown. Part of the first outside row 700 and part of the second outside row 702 on one side of the BGA 148, rows AA and AB, are shown in detail, as are part of the first outside column 704 and the second outside column 706 on one side of the BGA 148, columns 21 and 22. Balls 602 (shown in FIG. 6) are exemplary of the balls depicted by open circles in FIGS. 6 and 7 in the rows 700 and 702, the columns 704 and 706, and throughout the BGA. In some embodiments, three non-critical signal pins 708 are found as depicted by shaded circles at the corner of the BGA 148. The signal line 712 is exemplary of the many signal lines illustrated as short arrows running from the balls of the first outside row 700 and of the first outside column 704 directly out of the BGA 148. The signal line 714 is exemplary of the many signal lines running out of the BGA 148 from the balls of the second outside row 702 and of the second outside column 706 through spaces in between the balls of the first outside row 700 and the first outside column 704, respectively. Of the signal lines running out of the BGA 148 from the second outside row 702 and from the second outside column 706, only the first parts from the balls to the spaces between balls of the first outside row 700 and the first outside column 704 are shown. The reminders of the signal lines running out of the BGA 148 are omitted for clarity of illustration.

FIG. 8 illustrates a portion of the interior of the exemplary BGA layout embodiments of FIG. 6, partially populated with balls and spaces. The ball-space pair 800 is exemplary of the many ball-space pairs depicted as rectangles encompassing one ball 802 (such as a ball 602 as first shown in FIG. 6) and one space 804 unoccupied by a ball. The ball-space pair 800 includes signal line 806 from the ball 802 to the space 804, from which the signal line runs out of the BGA 148 through a via such as the via 1002 of FIG. 10, into the plane of the illustration of FIG. 8. Force common pins 808, pins that cannot be connected to signal lines running out of the array unless the pins are connected, i.e., made common, depicted as singly crosshatched circles, are representative of similarly depicted pins which must share a via with a representative ball 809.

Continuing reference to FIG. 8, first ball 810 is exemplary of a ball that can share a space 811 with a second ball 812. The space 811 and the second ball 812 make up the ball-space pair 818. The first ball 810 has a first signal line 814 running from it to the space, and the second ball 812 has a second line 816 running from it to the space. The first signal line 814 and the second signal line 816 connect the first ball 810 and the second ball 812 to the via 1002 of FIG. 10 in the space 811.

FIG. 9 depicts a portion of the interior of the exemplary BGA layout embodiments of FIG. 6, partially free of balls. A BGA 148 may include a portion that is not to be populated by balls. A portion of the exemplary area 900 illustrated in FIG. 10 is a die edge area that is to remain unpopulated by balls. In some circumstances, the presence of a die edge above solder balls of a BGA introduces stress to the solder balls, making it desirable to have the area below the die edge free of balls. In addition, in some circumstances, it may be desirable to have the area below the die edge free of balls to manage the thermal properties of the BGA. The portion of area 900 shown corresponds to row U from column 10 to column 17 and column 17 from row L to row U.

Turning now to FIG. 10, a cross-section of a portion of the exemplary BGA layout embodiments of FIG. 8 is illustrated. FIG. 10 shows the spatial relationships of the various items depicted to each other but is not drawn to scale. Specifically, a vertical cross-section of the BGA 148 through the first ball 810 and the second ball 812 is shown. The first ball 810 and the space 811 make up the ball-space pair 818. Within the ball-space pair 818 are the first signal line 814 and the second signal line 816, which are routed out of the BGA through the substrate layers 1000 through a hole via 1002. The hole via 1002 connects to a signal line 1004 running out of the BGA 148.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. A method for configuring a ball grid array, comprising:
identifying a number of balls for use in a ball grid array;
determining a number of rows and a number of columns for the ball grid array; and
populating the ball grid array at least in part with a plurality of ball-space groupings.

2. The method of claim 1, further comprising:
populating with balls at least one first outside row on a first side of the ball grid array, at least one second outside row on a second side of the ball grid array, at least one first outside column on a third side of the ball grid array, and at least one second outside column on a fourth side of the ball grid array.

3. The method of claim 1, wherein the plurality of ball-space groupings includes at least one ball-space pair.

4. The method of claim 1, wherein the plurality of ball-space groupings includes at least one ball-space-space triplet.

5. The method of claim 1, further comprising:
allocating an unpopulated portion of an area bounded by the at least one first outside row, the at least one second outside row, the at least one first outside column, and the at least one second outside column, to be free of balls.

6. The method of claim 1, further comprising:
routing a signal line from a ball of at least one ball-space grouping to a space of the at least one ball-space grouping; and
routing the signal line to a substrate layer through a via.

7. The method of claim 1, further comprising:
identifying a plurality of balls that can share a via;
adding a ball of the plurality of balls that share the via to a space of a ball-space grouping of the plurality of ball-space groupings; and
routing a first signal line from the ball of the plurality of balls that share the via to an adjacent space to share a via with a second signal line.

8. A system for configuring a ball grid array, comprising:
circuitry configurable for accepting input for identifying a number of balls for use in a ball grid array;
circuitry configurable for determining a number of rows and a number of columns for the ball grid array; and
circuitry configurable for populating the ball grid array at least in part with a plurality of ball-space groupings.

9. An article comprising a medium storing instructions that, if executed, enable a processor-based system to:
accept input to identify a number of balls required in a ball grid array;
determine a number of rows and a number of columns for the ball grid array; and
populate the ball grid array at least in part with a plurality of ball-space groupings.

10. The article of claim 9, comprising a medium storing instructions that, if executed, enable a processor-based system to:
populate with balls at least one first outside row on a first side of the ball grid array, at least one second outside row on a second side of the ball grid array, at least one first outside column on a third side of the ball grid array, and at least one second outside column on a fourth side of the ball grid array.

11. The article of claim 9, wherein the plurality of ball-space groupings includes at least one ball-space pair.

12. The article of claim 9, wherein the plurality of ball-space groupings includes at least one ball-space-space triplet.

13. The article of claim 9, comprising a medium storing instructions that, if executed, enable a processor-based system to:
allocate an unpopulated portion of an area bounded by the at least one first outside row, the at least one second outside row, the at least one first outside column, and the at least one second outside column, to be free of balls.

14. The article of claim 9, comprising a medium storing instructions that, if executed, enable a processor-based system to:
route a first signal line from a ball of at least one ball-space grouping to a space of the at least one ball-space grouping; and
route the signal line to a substrate layer through a hole via.

15. The article of claim 9, comprising a medium storing instructions that, if executed, enable a processor-based system to:
identify a plurality of balls that can share a via; and
add a ball of the plurality of balls that share the via to a space of at least one ball-space grouping of the plurality of ball-space groupings; and
route a first signal line from the ball of the plurality of balls that share the via to an adjacent space to share a via with a second signal line.

16. A computer system comprising:
a memory; and
a processor operably coupleable to the memory to
accept input to identify a number of balls required in a ball grid array,
determine a number of rows and a number of columns for the ball grid array, and
populate the ball grid array at least in part with a plurality of ball-space groupings.

17. An electronic device comprising:
an integrated circuit device including a ball grid array, the ball grid array including
at least one first outside row on a first side and at least one second outside row on a second side populated with balls;
at least one first outside column on a third side and at least one second outside column on a fourth side populated with balls; and
a populated portion of an interior area, wherein the populated portion of the area is populated with a plurality of ball-space groupings, and wherein the interior area includes an area bounded by the at least one first outside row, the at least one second outside row, the at least one first outside column, and the at least one second outside column.

18. The electronic device of claim 17, further comprising:
a memory operably coupleable to the integrated circuit device; and
a processor operably coupleable to the memory.

19. The electronic device of claim 17, wherein the plurality of ball-space groupings includes a ball-space pair.

20. The electronic device of claim 17, wherein the plurality of ball-space groupings includes a ball-space-space triplet.

21. The electronic device of claim 17, wherein the populated portion of the interior area comprises:
an unpopulated portion of the interior area, wherein the unpopulated portion of the area is free of balls.

22. The electronic device of claim 17, wherein the populated portion of the interior area comprises:
a signal line operably coupleable to a ball of at least one ball-space grouping of the plurality of ball-space groupings, operably coupleable to a space of the at least one ball-space grouping, and operably coupleable to a substrate layer through a via.

23. The electronic device of claim 17, wherein the populated portion of the interior area comprises:
at least one first ball that can share a via with a second ball, the first ball added to a space of at least one ball-space grouping; and
a first signal line from the at least one first ball to an adjacent space of a ball-space grouping, wherein the first signal line joins a second signal line from the second ball.
